(19) United States
(12) Patent Application Publication
(10) Pub. No.: US 2020/0174042 A1
(43) Pub. Date: Jun. 4, 2020

(54) HIGH-VOLTAGE IMPEDANCE ASSEMBLY

(71) Applicant: 3M INNOVATIVE PROPERTIES COMPANY, St. Paul, MN (US)

(72) Inventors: Michael H. Stalder, Uedem (DE); Sebastian Eggert-Richter, Wülfrath (DE); Rainer Fangrat, Erkrath (DE); Mark Gravermann, Erkelenz (DE); Jens Weichold, Erkelenz (DE); Gunther A.J. Stollwerck, Krefeld (DE); Bernd Schubert, Köln (DE); Hermanus Franciscus Maria Van Meijl, Someren-Eind (NL); Andreea Sabo, Düsseldorf (DE)

(21) Appl. No.: 16/620,665

(22) PCT Filed: Jun. 13, 2018
(86) PCT No.: PCT/IB2018/054310

§ 371 Date: Dec. 9, 2019

(30) Foreign Application Priority Data
Jun. 13, 2017 (EP) 17175652.1
Apr. 23, 2018 (EP) 18168697.3

(51) Int. Cl. G01R 15/06; H05K 1/18

(52) U.S. Cl. CPC G01R 15/06; H01G 4/38; H05K 1/18

(57) ABSTRACT

Impedance assembly (2) for use in a voltage divider for sensing an AC voltage of at least 1 kV versus ground of a power-carrying conductor distributing electrical energy in a grid. The impedance assembly comprises a) a printed circuit board (131) comprising one or more dielectric board layers (210, 215, 220), b) an externally accessible high-voltage contact (100), c) an externally accessible low-voltage contact (110), spaced from the high-voltage contact by at least 30 mm, and d) at least two dividing capacitors (91), connected in series between the high-voltage contact and the low-voltage contact and operable as a high-voltage side of the voltage divider. Each dividing capacitor has two electrodes formed by conductive areas (301, 302, 303, 304, 305, 306), arranged on opposed surface portions of a specific dielectric board layer, and a dielectric comprising a portion of the specific dielectric board layer on which the electrodes are arranged. Instead of the dividing capacitors, the impedance assembly may comprise a resistor layer.

The present disclosure relates to voltage dividers, and to capacitor assemblies and resistor assemblies for voltage dividers, that can be used for sensing voltages of inner conductors of medium-voltage (MV) or high-voltage (HV) power cables in national grids. It relates in particular to such voltage dividers, capacitor assemblies and resistor assemblies that can be accommodated in shrinkable or expandable or elastic sleeves for insulating such power cables. The disclosure also relates to kits comprising such capacitor assemblies or resistor assemblies and to cable terminations and cable plugs comprising such assemblies.

### BACKGROUND

Medium-voltage power cables transmit power at elevated voltages, typically alternating (“AC”) voltages of 1 kilovolt (“kV”) or higher versus ground. Voltages of high-voltage power cables are even higher. In both types of cables peak voltages can occur with voltages of about 75 kV or as high as 175 kV or even 194 kV. Where voltage dividers are used as elements of voltage sensors to sense the voltage of such cables, these dividers must be able to accommodate such peak voltages without being destroyed.

Voltage dividers for sensing a voltage of an inner conductor of an HV/MV power cable are known, e.g. from the German patent applications DT 24 39 080 A1 or DE 3702735 A1. Voltage dividers can be formed by a plurality of resistors, capacitors or inductances. Resistors, capacitors and inductances are collectively referred to as impedance elements or impedances in this disclosure.

Voltage sensors can advantageously be accommodated in cable terminations or in separable connectors such as cable plugs. Certain ones of these terminations and plugs comprise expandable or shrinkable tubular sleeves of an insulating material, with a passageway in which the end of the cable can be received. A portion of a voltage sensor, e.g. the voltage divider, can be placed into a cavity of the insulating sleeve, adjacent to the passageway. Such an arrangement offers the advantage that the insulating material of the sleeve can be used to also insulate the voltage divider, and permits wires connecting the voltage divider to the inner connector of the cable to be shorter.

The withstand voltage of a single capacitor or of a single resistor is normally lower than the 1 kV mentioned above. Therefore, traditionally, a larger number of discrete impedances or impedance elements were connected electrically in series to form a voltage divider between high voltage and ground, so that the voltage drop across each impedance was sufficiently low to avoid electrical discharges. The large number of impedance elements can have an impact on the manufacturing cost of such voltage divider chains.

Where the voltage divider of the voltage sensor is accommodated in an insulating sleeve of a termination or of a cable plug, the geometric length of the sleeve poses limitations on the geometric length of the voltage divider. Typical MV cable terminations have a length of 30-50 centimetres (cm), as measured along the cable. The length of the voltage divider should thus not exceed this length, if it is to be accommodated in the termination. One end of the voltage divider is arranged next to the high voltage of the inner conductor, while the opposed end is next to low voltage, mostly ground. The voltage of the inner conductor, i.e. at least 1 kV and up to 175 kV, thus needs to be divided down to zero volt (electrical ground), or to almost zero volt, over this geometric length. In order to reduce the risk of electrical discharges between the high-voltage end of the voltage divider and its low-voltage end, an exposed contact of the first impedance element of the voltage divider, which is connected to the medium or high voltage of the inner conductor, is advantageously arranged geometrically as far as possible from an exposed contact of the last impedance element of the voltage divider, connected to ground.

Where high precision is required in measuring the voltage of the inner conductor, it should be considered that commercially available capacitors and resistors exhibit some variation of their capacitances and resistances with temperature and ambient humidity. Their capacitances and resistances also vary with their age. These factors lead to unpredictable changes over time in the electrical properties of the impedance elements forming a voltage divider chain, which are reflected in unpredictable variations of the divider ratio of the voltage divider in which the impedance elements are used to divide voltage. Due to these variations, some traditional voltage sensor are less precise in sensing the voltage of the inner conductor.

### SUMMARY

A voltage divider for an AC voltage sensor on an MV/HV power cable according to the present disclosure should survive peak voltages of up to 175 kV, preferably of up to 200 kV, without being destroyed. It should be able to measure voltages of at least twice the “normal” voltage of the inner conductor versus ground in a normal state of the power network. In medium-voltage power networks, this normal voltage is often considered to be 20.8 kV, and the sensor is thus designed to measure voltages of at least about 42 kV. The voltage divider of the sensor should advantageously provide an electrical output signal that can be processed by standard electronic circuitry, such as an output signal of between 1 Millivolt (mV) and 10 Volt. This target output voltage and the 1 kV to 42 kV voltage range of the inner conductor requires a certain dividing ratio of the voltage divider, namely a dividing ratio in the range of about 1:100 up to about 1:4200 for MV cables and correspondingly higher for HV cables. In order for a sensor to be usable with a variety of different cables, a suitable target dividing ratio may be about 1:10000. The impedance of the high-voltage side of the voltage divider thus needs to be about 10000 times as high as the impedance of the low-voltage side of the voltage divider. For a capacitive voltage divider, this requires the capacitance of the high-voltage side to be about 1:10000 of the capacitance of the low-voltage side.

It is desirable to provide components of AC voltage dividers for accommodation in MV/HV cable terminations or cable plugs that reduce the risk of electrical discharge. The components should also provide for a divider ratio that allows connection to common electronic circuitry. It is further desirable that such components be more cost-efficient. It is also desirable to provide such components that are less susceptible to aging effects and environmental impacts.

The present disclosure attempts to address these needs. According to a fundamental aspect of this disclosure, it provides an impedance assembly for use in a voltage divider for sensing an AC voltage of at least 1 kV versus ground of a power-carrying conductor distributing electrical energy in a national grid, wherein the impedance assembly comprises
a) a printed circuit board comprising one or more dielectric board layers,
b) an externally accessible high-voltage contact,
c) an externally accessible low-voltage contact, wherein any externally accessible portion of the low-voltage contact is spaced from any externally accessible portion of the high-voltage contact by a geometrical distance of at least 30 mm, and
d) at least two dividing capacitors, electrically connected in series between the high-voltage contact and the low-voltage contact and operable as a high-voltage side of the voltage divider,

wherein each dividing capacitor has two electrodes formed by opposed conductive areas, arranged on opposed surface portions of a specific dielectric board layer of the one or more dielectric board layers, and a dielectric arranged between the electrodes and comprising a portion of the specific dielectric board layer on which the electrodes are arranged.

The impedance assembly according to this first fundamental aspect of the present disclosure comprises at least two dividing capacitors. It is therefore also referred to as a “capacitor assembly” herein. It may form a component of a voltage divider. The printed circuit board (“PCB”) provides for a particularly rugged and reliable support for the opposed conductive areas of the capacitor electrodes on its dielectric board layers. The arrangement of the high-voltage contact and the low-voltage contact at a distance of at least 30 mm from each other reduces the risk of discharges between these contacts.

Generally, the impedance assembly may have an elongate shape. The elongate shape may define a length direction and opposed end portions. In particular, the impedance assembly may be suitably shaped to be accommodated in a longitudinal cavity of an elongate elastic sleeve for insulating the power cable. This shape facilitates placement of the impedance assembly in a cable termination, a cable plug or a similar cable accessory which comprises an elastic sleeve. Placement in the sleeve is advantageous in that the existing insulation material of the sleeve may be used to also insulate the impedance assembly, whereby the risk of discharges across the impedance assembly is reduced, and no separate dedicated insulation for the impedance assembly needs to be provided.

The voltage drop across the impedance assembly from high voltage to low voltage is effected over at least two dividing capacitors. This minimum number of dividing capacitors ensures that the voltage drop across each dividing capacitor is moderate and, as a result, that the risk of electrical discharge across each dividing capacitor is low.

These at least two dividing capacitors may be electrically connected in series between the high-voltage contact and the low-voltage contact such as to provide a combined capacitance of at least 10 picofarad (pF). This combined capacitance, at a given dividing ratio of about 1:10,000, allows the low-voltage side capacitor of the voltage divider to have a capacitance of about 100 nanofarad (nF). Such capacitors of about 100 nF are available at reasonable cost, with accuracies of 1% and acceptable capacitance variations with varying temperature and age, e.g. according to NP0.

The construction of the dividing capacitors from conductive areas forming their electrodes and a portion of the PCB dielectric board layer forming their dielectric is advantageous over the use of prefabricated discrete capacitors in that it allows tailoring of the accuracy and of the withstand voltage to the required degree. A suitable choice of the material of the PCB of the impedance assembly, for example, may result in an acceptable degree of variation of the capacity with variations in ambient temperature or humidity. Also, suitably choosing an appropriate spacing between the opposed conductive areas can help obtain the desired capacity.

An impedance assembly according to the first fundamental aspect of the present disclosure may be a voltage divider for sensing a voltage of at least 1 kV vs. ground of an inner conductor of a power-carrying conductor distributing electrical energy in a national grid. Alternatively, an impedance assembly according to the first fundamental aspect of the present disclosure may be a component of such a voltage divider or comprise a component of such a voltage divider. In some embodiments, the impedance assembly comprises the high-voltage portion of a voltage divider for sensing an AC voltage of at least 1 kV vs. ground of a power-carrying inner conductor of a power cable distributing electrical energy in a national grid.

Voltages of 1 kV vs. ground or higher can be measured using voltage dividers, such as capacitive or resistive voltage dividers. In a voltage divider, at least two impedance elements (“dividing impedances”) are electrically connected in series between the high voltage to be measured and electrical ground. The term “impedance” or impedance element as used for a physical element refers herein either to a resistor, a capacitor or to an inductor. In certain contexts, the term “impedance” is also used herein for the electrical property of the physical element, i.e. the resistance of a resistor, the capacitance of a capacitor or the inductance of an inductor. Between the at least two dividing impedances forming the voltage divider, a voltage (“sensing voltage”) can be picked up which is proportional to the high voltage, with the proportionality factor or “divider ratio” being the ratio of the value of the high-voltage impedance (i.e. the impedance element connected directly to high-voltage) to the value of the low-voltage impedance (i.e. the impedance element connected directly to ground).

Voltage dividers in which all dividing impedance elements are resistors are generally referred to herein as resistive voltage dividers, while voltage dividers in which all dividing impedance elements are capacitors are referred to herein as capacitive voltage dividers. Alternatively, a voltage divider can be mixed, that is, one dividing impedance is of one type (resistor, capacitor, or inductor), the other dividing impedance is of a different type, resulting in combinations such as resistor-capacitor, inductor-resistor, etc.

A dividing impedance is not necessarily a single resistor, capacitor or inductor, but can alternatively be made up of two or more impedance elements. A voltage divider may, therefore, either comprise a single dividing impedance element or a chain of dividing impedance elements, electrically connected in series. Between two of the dividing impedance elements of a chain, at a midpoint or access location or “pick-up point”, the sensing voltage can be picked up. All impedance elements of the voltage divider which are electrically connected between the pick-up point and high voltage form the “high-voltage side” of the divider, and all impedance elements of the divider which are electrically connected between the pick-up point and ground form the “low-voltage side” of the voltage divider.

The term “power-carrying conductors” refers herein to elements through which electrical power can flow at voltages above 1 kV and high currents of tens or hundreds of amperes. Examples of power-carrying conductors are busbars, e.g. in switchgears, bushings, or power cables, in particular the inner conductor(s) of power cables. Power-carrying conductors, with which the present impedance assembly can be used, are, for example, power cables transmitting electrical power over large geographic distances in a national grid. Medium-voltage (MV) and high-voltage (HV) power cables are operated at voltages of 1 kV vs. ground or higher and are designed for currents of tens or hundreds of amperes.

Such power cables mostly comprise a central inner conductor having a diameter of 8 millimetres or more, which transmits the electrical power and carries the current. The inner conductor is surrounded coaxially by a layer of insulating material forming the main insulation of the cable, which in turn carries on its outer surface a semiconductive layer. Other layers may be present, including, for example, a shielding mesh. An insulating cable sheath forms the outermost layer of the cable.

Impedance assemblies according to the present disclosure may be designed to be accommodated in a longitudinal cavity of an elastic sleeve for insulating the power cable. Such sleeves are often comprised in cable terminations, cable plugs or cable splices, but can also be used alone. The sleeves have a passageway, in which a longitudinal section of the cable, of a stripped cable or of the inner conductor alone can be received. These sleeves are elastic, as they are designed to be elastically expandable to receive the cable, or elastically shrinkable around the cable. Typical elastically expandable sleeves can be pushed coaxially over the main insulation at an end of the cable, thereby expanding, and by their elastic contraction creating friction to maintain their position on the cable. Elastically shrinkable sleeves can be applied over a section of the cable while held in an expanded state, whereafter they are shrunk down over the cable, for example by applying heat, by removing a support, or in other manners.

Besides the passageway, some sleeves have a longitudinal cavity in their insulation material, extending parallel to the passageway. In this cavity a component of a voltage divider, such as an impedance assembly according to the present disclosure, can be accommodated. Since this cavity is formed in the sleeve, it is close to the inner conductor of the cable, so that any connecting wires can be shorter. Also, this arrangement makes use of the existing insulation in the sleeve. The cavity can be insulated by the insulation material that is arranged around the passageway. Sleeves that are to accommodate, besides the cable, components of a voltage divider can be sized appropriately to insulate both the cable and the components of the voltage divider properly. Normally, no or little additional insulation material is required, compared to sleeves for insulation of the cable only.

Such elastic sleeves may have the shape of an elongate tube, extending longitudinally in the direction of the passageway. The cavity may be elongate and extend longitudinally in the direction of the passageway. The cavity and the passageway may be separated by insulation material. The cavity may have a length of between 20 cm and 50 cm. Correspondingly, the impedance assembly may have a length of between 10 cm and 100 cm, in particular of between 20 cm and 50 cm. However, the length of the cavity is generally independent of the length of the passageway or the length of the sleeve. The cavity may be shorter than the passageway or the sleeve.

Elastic sleeves as described above may be comprised in cable splices, in separable connectors such as cable plugs, or in cable terminations. Such elastic sleeves may be equipped with sheds to provide a longer creep current path along the outer surface of the sleeves. They may be equipped with stress control portions for shaping the electrical field.

The PCB in an impedance assembly according to the present disclosure comprises one or more dielectric board layers. Where the PCB comprises two or more dielectric board layers, it is also referred to as a multilayer PCB.

Generally, the PCB of the present impedance assembly is electrically non-conductive, and the dielectric board layer(s) of the PCB is/are non-conductive. At least a portion of a dielectric board layer of the PCB is operable as a dielectric of a dividing capacitor.

In certain embodiments, the PCB is a multilayer PCB. A multilayer PCB may comprise at least two conductive areas arranged in the interior of the PCB. The two conductive areas may form electrodes of one of the at least two dividing capacitors. Hence, in certain embodiments, the printed circuit board is a multilayer printed circuit board, and at least two of the conductive areas are arranged in the interior of the printed circuit board.

Conductive areas in the interior of the PCB are conductive areas inside the PCB, or embedded in the PCB, as opposed to conductive areas on an outer surface of the PCB. A conductive area in the interior of the PCB may still be exposed and/or externally accessible at an edge of the PCB. Conductive areas in the interior of the PCB and any non-conductive dielectric layers between these conductive areas are better protected against certain environmental impacts by corrosion, temperature or humidity, for example.

In certain embodiments, the PCB is a multilayer PCB comprising two conductive areas in the interior of the PCB and two further conductive areas on outer surfaces of the PCB. The PCB may thus comprise four conductive areas, of which two are in the interior of the PCB, and of which the other two are on the PCB.

Generally, a dielectric board layer in the PCB may carry conductive areas on opposed portions of its surface. This may help obtain larger capacitances of the dividing capacitors. The number of dielectric board layers of the PCB is generally not limited. The dielectric board layer(s) must be sufficiently thick to reduce the risk of electrical discharges between conductive areas on opposed portions of their surface and thus to be usable as a dielectric for dividing capacitors at voltages of 1 kV or higher. The usability of dielectric board layers as a dielectric also depends on their electrical properties, such as their dielectric strength or electrical strength.

The impedance assembly may have an elongate shape, for example a flat rectangular shape. The rectangular shape defines a length and a width. The impedance assembly may have a rectangular shape having a length of between 10 cm and 50 cm, in particular a length of between 15 cm and 35 cm. It may have a rectangular shape having a width of between 1 cm and 5 cm, in particular a width of between 2 cm and 3 cm.

Where the impedance assembly has an elongate shape, the elongate shape defines a first end portion and an opposed second end portion. The end portions may be spaced from each other in a length direction of the impedance assembly.

The elongate shape of the impedance assembly may be defined by the shape of the PCB.

The expression “externally accessible contact” refers herein to the contact being arranged suitably to allow access from outside the PCB for the purpose of securing a wire to the contact, and/or to establish a surface contact with it in order to determine its voltage. For instance, a contact on an outer surface of the PCB is an externally accessible contact.

An impedance assembly according to the present disclosure comprises an externally accessible high-voltage contact. Where the impedance assembly has an elongate shape, the high-voltage contact may be arranged at a first end portion of the impedance assembly. The high-voltage contact is suitable for a wired connection to the power-carrying conductor, e.g. to the inner conductor of a power cable. The high-voltage contact may comprise, for example, a soldering point to which a wire can be secured that is connected to the power-carrying conductor. Alternatively, the high-voltage contact may be comprised, for example, in a connector, with which a matching connector can be mated to establish a connection with the inner conductor. In specific embodiments, the high-voltage contact is an exposed soldering point on an outer surface of the printed circuit board.

The impedance assembly also comprises an externally accessible low-voltage contact. Where the impedance assembly has an elongate shape, where the high-voltage contact is arranged at a first end portion of the impedance assembly, the high-voltage contact may be arranged at the second end portion of the impedance assembly. The low-voltage contact is suitable for connection to ground or to a low voltage of 10 V or less. The low-voltage contact may comprise, for example, a soldering point to which a wire can be secured for connection to a grounding element. Alternatively, the low-voltage contact may be comprised, for example, in a connector, with which a matching connector can be mated to establish an electrical connection to a grounding element. In specific embodiments, the low-voltage contact is an exposed soldering point on an outer surface of the printed circuit board.

In certain embodiments, the low-voltage contact may be the ground contact of the voltage divider for sensing the voltage of the power-carrying conductor. In these embodiments, all electrical elements of the voltage divider, including its high-voltage side and its low-voltage side, may be accommodated on the PCB. The low-voltage side may comprise capacitors forming a total capacitance of between 20 nF and 500 nF, particularly of between 40 nF and 100 nF.

In other, alternative embodiments, the low-voltage contact may be the midpoint contact or pick-up contact of the voltage divider. In these embodiments, electrical elements (e.g. impedance elements) of the voltage divider forming its high-voltage side may be accommodated on the PCB. Electrical elements, such as impedance elements, forming the low-voltage side of the voltage divider may be accommodated on the PCB or off, i.e. remote from, the PCB.

Any externally accessible portion of the low-voltage contact is spaced from any externally accessible portion of the high-voltage contact by a geometrical distance of at least 30 millimetres (mm). This distance helps reduce the risk of electrical discharge between the high-voltage contact and the low-voltage contact. Where the high-voltage contact is arranged at the first end portion of the impedance assembly, the low-voltage contact may be arranged at the opposite, second end portion. In certain embodiments, however, a higher risk of electrical discharge may exist. In such embodiments the externally accessible portion of the low-voltage contact may be spaced from the externally accessible portion of the high-voltage contact by a distance of at least 50 mm, or of at least 100 mm. The distance is to be measured purely geometrically, as the length of a straight line between the respective externally accessible portions of the high-voltage contact and the low-voltage contact closest to each other. Conductive traces or exposed wire portions leading towards the high-voltage contact or towards the low-voltage contact are not supposed to be considered portions of the respective contact, as they are not adapted for connection, e.g. mechanical connection, to a wire or to a connector.

A capacitor assembly according to the present disclosure comprises at least two dividing capacitors, electrically connected in series between the high-voltage contact and the low-voltage contact of the impedance assembly. These dividing capacitors may form the high voltage side, or a portion of the high-voltage side, of the voltage divider for sensing the voltage of the inner conductor.

The inventors of the present disclosure have discovered that a smaller number of dividing capacitors can result in too high electrical field strength across each dividing capacitor and, as a result, in a higher risk of electrical discharge across one of the dividing capacitors.

A greater number of dividing capacitors, e.g. three, four, five, six, seven, eight, nine, ten or even more, will reduce electrical field strength across each individual capacitor, but the resulting accumulated capacitance of the dividing capacitors will become smaller and smaller. In order to achieve a combined capacitance of at least 10 pF for a useful dividing ratio of the voltage divider, each individual capacitor would have to have a larger capacitance, but a smaller geometric footprint. The inventors of the present disclosure contemplate a maximum number of twenty dividing capacitors. So in certain embodiments, the impedance assembly may comprise four, five, six, seven or eight dividing capacitors. In certain other embodiments, it may comprise between two and twelve dividing capacitors, and in certain other embodiments, it may comprise between two and twenty dividing capacitors.

In a specific embodiment, the impedance assembly comprises a total of six dividing capacitors, electrically connected in series between the high-voltage contact and the low-voltage contact such as to provide a combined capacitance of at least 10 picofarad, and operable as a high-voltage side of the voltage divider between the low voltage and the high voltage of the power-carrying conductor, wherein each dividing capacitor has two electrodes formed by opposed conductive areas arranged on opposed surface portions of a specific dielectric board layer of the one or more dielectric board layers, and a dielectric arranged between the electrodes and comprising a portion of the specific dielectric board layer on which the electrodes are arranged.

For many common geometries of impedance assemblies and many material properties of dielectrics of impedance assemblies, this number of six dividing capacitors appears to provide a good balance between discharge risk across a dividing capacitor and the achievable combined capacitance of the dividing capacitors.

In all these embodiments, the dividing capacitors are electrically connected in series between the high-voltage contact and the low-voltage contact such as to provide a combined capacitance of at least 10 pF, and may be operable as high-voltage side of the voltage divider between the low voltage and the high voltage of the power-carrying conductor.

Voltage dividers, in which impedance assemblies according to the present disclosure can be used, preferably provide an output voltage, as picked up at the midpoint, that can be processed in standard electronic circuitry, for example an output voltage of between 1 Millivolt and 10 Volt, advantageously having a dividing ratio of about 1:10000. Fora given dividing ratio, a lower overall capacitance of the high-voltage side of the voltage divider requires a lower overall capacitance of the low-voltage side. Due to the high dividing ratio, it is generally desirable for the high-voltage side to have a larger overall capacitance and a corresponding lower impedance. Larger capacitances for the high-voltage side of a voltage divider render the voltage divider less sensitive to effects of parasitic capacitance and increase the precision of the voltage sensing. They are, however, harder and more costly to build where space is restricted.

Which dividing ratio is desired may depend, inter alia, on the expected voltage of the inner conductor, and/or on the desired sensor output voltage at the midpoint of the voltage divider. Therefore, in certain embodiments of the present disclosure, the at least two dividing capacitors provide a combined, i.e. overall, capacitance of at least 10 pF. In certain of those embodiments, the at least two dividing capacitors are electrically connected in series between the high-voltage contact and the low-voltage contact such as to provide a combined capacitance of at least 20 pF or of at least 50 pF or of at least 100 pF. In certain embodiments, the at least two dividing capacitors are electrically connected in series between the high-voltage contact and the low-voltage contact such as to provide a combined, i.e. overall, capacitance of between 10 pF and 100 pF or of between 20 pF and 60 pF.

Each of the at least two dividing capacitors has two electrodes and a dielectric. The electrodes of each of the at least two dividing capacitors are formed by opposed conductive areas on opposed surface portions of a specific dielectric board layer of the one or more dielectric board layers of the PCB. The dividing capacitors are thus no discrete surface-mounted components, also referred to as SMDs in this field. Rather they are made of conductive areas on or in the PCB, which are opposed to each other, so that they form capacitor plates. The opposed conductive areas may be parallel to each other. Where two conductive areas form the electrodes of a dividing capacitor, only a portion of one conductive area may be opposed to the other conductive area.

A conductive area may comprise, for example, a layer of conductive metal such as copper, silver or gold. Such a layer of conductive metal may be arranged, e.g. coated, on a surface portion of a dielectric board layer. A conductive area may have a thickness of, for example, between 1 μm and 100 μm.

The conductive areas may be arranged on the PCB or in the PCB. A conductive area may, for example, be arranged on an outer surface of the PCB. Such an arrangement facilitates establishment of an electrical contact with the conductive area, e.g. by soldering or surface contact, because the conductive area on an outer surface of the PCB is particularly well accessible.

A conductive area may be arranged in the PCB. Where the PCB is a multilayer PCB, a conductive area may be formed by a conductive patch or a conductive coating on an inner dielectric board layer of the PCB. A conductive area arranged in the PCB, e.g. arranged on a surface portion of an inner dielectric board layer, may comprise a portion which is externally accessible, e.g. accessible at an edge of the PCB.

A conductive area may be co-extensive with the PCB. Alternatively, a conductive area may extend over only a portion of the PCB. For example, where the PCB is a flat, rectangular body of 20 mm by 250 mm size (and a thickness of, say, about 1 mm), a conductive area in or on the PCB may have a size of 20 mm by 50 mm.

Where the electrodes of a dividing capacitor are formed by two opposed conductive areas, both conductive areas may be arranged on outer surfaces of the PCB. Where the PCB is a single-layer PCB, i.e. it has only one dielectric board layer, the conductive areas of all of the at least two dividing capacitors may be arranged on opposed outer surfaces of the PCB. Alternatively, where the PCB has two or more dielectric board layers, conductive areas of all of the at least two dividing capacitors may be arranged in the PCB. Alternatively, one of the conductive areas may be arranged on the PCB, and the other conductive areas may be arranged in the PCB.

Each of the at least two dividing capacitors comprises a dielectric which comprises a portion of the specific dielectric board layer on which the electrodes of the respective dividing capacitor are formed. The dielectric properties of the PCB and of its dielectric board layers may have a bearing on the capacitance of the at least two dividing capacitors. The PCB substrate material(s) may thus be suitably chosen, for example, to minimize the effect of temperature variations on the capacitance of the dividing capacitors. Ceramic materials are known to have certain dielectric properties that vary comparatively little with temperature at temperatures where power cables are typically used. Therefore, in certain preferred embodiments, the printed circuit board is a ceramic PCB. In certain of these embodiments, the printed circuit board is a ceramic multilayer PCB. Independent from a PCB being a single-layer PCB or a multilayer PCB, at least one of its dielectric board layers may comprise a ceramic material. In certain preferred embodiments of the impedance assembly according to the present disclosure, each dielectric board layer of the PCB comprises a ceramic material.

The materials forming the dielectric board layers may be chosen, for example, suitably to minimize the effect of humidity variations on the capacitance of the at least two dividing capacitors. Again, ceramic materials are known to have dielectric properties that vary comparatively little with variations in ambient humidity, and may therefore be suitable materials for dielectric board layers of the PCB or the entire PCB.

The PCB is generally electrically non-conductive. The portions of a dielectric board layer forming the dielectric of a dividing capacitor are electrically non-conductive. The PCB of an impedance assembly according to the present disclosure may be a mechanical support for other elements of the impedance assembly. The high-voltage contact may be supported by the PCB. The low-voltage contact may be supported by the PCB.

The individual dielectric board layers of the PCB may be formed of, or comprise, a ceramic material, such as a hydrocarbon ceramics material, or combinations of woven glass fibres and epoxy resin such as those in materials known as FR3, FR4 or FR5. A dielectric board layer may be, or comprise, a PTFE (polytetrafluoroethylene) material, a PEEK (polyether ether ketone) material, an LCP (liquid crystal polymer) material, a polyimide material or an epoxy material. A dielectric board layer may comprise mixtures or combinations of these materials, such as, for example, in ceramic-filled PTFE PCBs.

In certain embodiments, the PCB is a ceramic body, i.e. the PCB has only one dielectric board layer of a ceramic material. The ceramic body may be a solid body having no internal structure, e.g. no internal layer structure. The ceramic body may support, on its outer surfaces, the conductive areas forming the electrodes of the dividing capacitors. Ceramic bodies may be particularly cost-effective to manufacture, and may be rugged to withstand mechanical forces.

Examples of ceramic materials that can be used for dielectric board layers of PCBs in impedance assemblies as described herein are silicon nitride, aluminium oxide such as Al₂O₃, aluminium nitride such as AlN, and low-temperature cofire ceramics.

In order to reduce the risk of electrical discharges between elements of an impedance assembly, the impedance assembly, or portions of it, may be embedded in an electrically non-conductive encapsulating material. The encapsulating material may be a hardened resin, for example. Where the impedance assembly has an elongate shape, a middle portion of the impedance assembly may be embedded in the encapsulating material, while the end portions may be free of encapsulating material. In certain embodiments, at least a portion of the impedance assembly is embedded in an electrically non-conductive encapsulating material. In certain embodiments, the impedance assembly has an elongate shape, and at least 50% of the geometric length of the impedance assembly is embedded in an electrically non-conductive encapsulating material. In some embodiments, at least 50%, or at least 70%, of the geometric length of the impedance assembly is embedded in encapsulating material. In another specific embodiment, 100% of the geometric length of the impedance assembly, i.e. the entire impedance assembly, is embedded in encapsulating material.

Where the impedance assembly is embedded, partially or entirely, in an electrically insulating encapsulating material, a conductive layer may be applied on the outer surface of the encapsulating material to form a shielding of the impedance assembly. Conventionally, this shielding layer or screen is held on electrical ground. A screen on electrical ground, however, causes parasitic currents through the encapsulation material, between elements of the impedance assembly on higher voltage and the screen. Parasitic currents are undesired, because they can reduce the accuracy of the voltage sensing mechanism, in particular because their magnitude may vary uncontrollably with temperature and/or humidity of the encapsulation material.

Conventionally, a screen is held on one electrical potential, e.g. on ground. Since a dividing capacitor close to the high-voltage portion (i.e. the portion comprising the high-voltage contact) of the impedance assembly is on a higher voltage than a dividing capacitor close to the opposed low-voltage portion (i.e. the portion comprising the low-voltage contact) of the impedance assembly, the voltage difference to the screen varies along the extension of the impedance assembly, and from one dividing capacitor to an adjacent dividing capacitor, and so vary the resulting parasitic currents. A higher voltage difference normally results in higher parasitic currents.

In an attempt to reduce these parasitic currents, it has been found that it is advantageous to split the screen into two conductive portions, separated by an intermediate insulating gap: A low-voltage screen portion is applied on the outer surface of the encapsulating material enveloping the low-voltage portion of the impedance assembly, and is held on electrical ground or on a low voltage, while a high-voltage screen portion is applied on the outer surface of the encapsulating material enveloping the high-voltage portion of the impedance assembly, and is held on high voltage.

As a result, the dividing capacitors in the low-voltage portion are shielded by a screen on electrical ground or on low voltage, which reduces voltage differences and parasitic currents. Similarly, the dividing capacitors in the high-voltage portion are shielded by a screen on high voltage, which reduces voltage differences and parasitic currents in the high-voltage portion of the impedance assembly.

An intermediate portion of the outer surface of the encapsulation material enveloping the impedance assembly, namely a portion enveloping the intermediate portion of the impedance assembly between the high-voltage portion and the low-voltage portion of the impedance assembly, is not provided with a screen. This unshielded gap is necessary to avoid electrical discharges between the high-voltage screen and the low-voltage screen.

So generally, in certain embodiments of the impedance assembly according to the present disclosure, in which at least a portion of the impedance assembly is embedded in an electrically non-conductive encapsulating material, the outer surface of the encapsulation material comprises
a first surface region covered with an electrically conductive layer for being connected to high voltage;
a second surface region covered with an electrically conductive layer for being connected to electrical ground; and
a third surface region, electrically insulating and free of an electrically conductive layer, arranged between the first and the second surface region, for insulating the first surface region from the second surface region.

The first surface region may be arranged and sized such as to form a conductive envelope around the low-voltage portion of the impedance assembly. The second surface region may be arranged and sized such as to form a conductive envelope around the high-voltage portion of the impedance assembly.

In a specific embodiment, in which the impedance assembly has an elongate shape and is entirely embedded in an electrically non-conductive encapsulating material, and in which the low-voltage portion and the high voltage portion are arranged at opposed end portions of the impedance assembly, the first surface region of the encapsulation material is covered with an electrically conductive layer for being connected to high voltage, which envelopes the high-voltage portion. The second surface region of the encapsulation material is covered with an electrically conductive layer for being connected to low voltage or electrical ground, which envelopes the low-voltage portion. In a central surface region of the encapsulation material, enveloping the middle portion of the impedance assembly, between the first and the second surface region, there is no conductive layer, and this electrically insulating gap separates the first surface region and the second surface region from each other.

Certain impedance assemblies according to the present disclosure may be shaped such as to be suitable for accommodation in a longitudinal cavity of an elastic sleeve for insulating a power cable. Such sleeves are used, inter alia, for cable terminations, cable plugs and cable splices. The length of such terminations, plugs, splices and sleeves is often 30 centimetres or less. To facilitate accommodation in such plugs, splices and sleeves, in certain embodiments of the present disclosure, the impedance assembly has an elongate shape and a length of 30 centimetres or less. In certain of these embodiments, the impedance assembly has a length of 20 centimetres or less, or of 10 cm or less, or even of 5 cm or less. The length is to be measured geometrically in the length direction of the cable on which the termination, splice, plug or sleeve is arranged when in use. For very short impedance assemblies, additional insulation may be necessary in order to reduce the risk of electrical discharges.

In one aspect, the present disclosure provides a sensored cable accessory comprising a) a cable termination, comprising an elastic sleeve for electrically insulating a power-carrying conductor of a power cable, the sleeve having a longitudinal cavity for accommodating an impedance assembly as described herein, and b) an impedance assembly as described herein, arranged in the cavity of the sleeve.

In another aspect, the present disclosure provides a sensored cable accessory comprising a) a cable plug, comprising an elastic sleeve for electrically insulating a a power-carrying conductor of power cable, the sleeve having a longitudinal cavity for accommodating an impedance assembly as described herein, and b) an impedance assembly as described herein, arranged in the cavity of the sleeve.

The sleeve may be formed in a molding process, where a hollow mold determining the shape of the sleeve is filled with a liquid molding material which then solidifies and forms the sleeve. In certain embodiments according to the present disclosure, the impedance assembly, embedded in an electrically non-conductive encapsulating material or not, is placed in the mold just before the sleeve is molded. The impedance assembly is thereby molded into the sleeve. The cavity of the sleeve, in this case, takes the exact shape of the impedance assembly. This reduces the occurrence of air pockets, the existence of which otherwise may lead to a higher risk of electrical discharges.

Instead of dividing capacitors being connected between the high-voltage contact and the low-voltage contact, an impedance assembly according to the present disclosure may comprise a resistor layer connected between the high-voltage contact and the low-voltage contact, operable as a high-voltage side of the voltage divider.

Hence, in a second fundamental aspect of this disclosure, it is provided an impedance assembly for use in a voltage divider for sensing an AC (i.e. alternating) voltage of between 6 kV and 175 kV of an inner conductor of a power cable distributing electrical energy in a grid, wherein the impedance assembly has an elongate shape defining a first end portion and an opposed second end portion, for accommodation in a longitudinal cavity of an elastic sleeve for insulating the power cable, and wherein the impedance assembly comprises
a) a substrate,
b) a high-voltage contact, arranged at the first end portion, for galvanic connection to the inner conductor,
c) a low-voltage contact, arranged at the second end portion at a distance of at least 10 centimetres from the high-voltage contact, for electrical connection to a low voltage of 10 volt or lower, and
d) a resistor layer, arranged on an inner or an outer surface of the substrate and extending between the first end portion and the second end portion, electrically connected in series between the high-voltage contact and the low-voltage contact such as to provide a resistance of at least 50 MΩ (Mega Ohm), wherein the resistor layer is operable as a high-voltage side of the voltage divider between the low voltage and the high voltage of the inner conductor.

The impedance assembly according to this second fundamental aspect (also referred to herein as the “resistor assembly”) provides a resistor in the form of a resistor layer for the high-voltage side of the voltage divider for sensing the voltage of the inner conductor, which is the power-carrying conductor of a power cable. The resistor layer forms an impedance in the voltage divider. The voltage divider may be a resistive voltage divider or a mixed voltage divider.

Several components of the resistor assembly, such as the substrate, the high voltage contact or the low voltage contact, are also comprised in the capacitor assembly according to the first fundamental aspect of the disclosure described above. These components fulfil the same functions in both impedance assemblies and will therefore not be explained again.

The resistor assembly may form a component of a voltage divider. The elongate shape of the resistor assembly facilitates its accommodation in a sleeve of a cable termination or of a cable plug. The arrangement of the high-voltage contact and the low-voltage contact at opposed ends of the resistor assembly, at a distance of at least 10 cm from each other, reduces the risk of discharges between these contacts.

The resistor assembly is suitably shaped to be accommodated in a longitudinal cavity of an elongate elastic sleeve for insulating the power cable. This shape facilitates placement of the resistor assembly in a cable termination, cable plug or a similar cable accessory which comprises an elastic sleeve. Placement in the sleeve is advantageous in that the existing insulation of the sleeve may be used to also insulate the resistor assembly, whereby the risk of discharges across the resistor assembly is reduced, while no dedicated insulation for the resistor assembly needs to be provided.

The voltage drop across the voltage divider from high voltage to low voltage is effected over the resistor layer, which provides a resistance of at least 50 MΩ. The resistance of the resistor layer, in combination with its geometric extension between the first end portion and the second end portion of the resistor assembly, ensures that the voltage drop per unit length across the resistor layer is moderate and, as a result, that the risk of electrical discharge across the resistor layer is low.

The construction of a resistor via a resistor layer is advantageous over the use of prefabricated discrete resistors in that it allows tailoring of the accuracy of the resistance and of the breakdown voltage to the required degree. Also, discrete resistors having a suitable geometric extension may be difficult to obtain.

A resistor assembly according to the second fundamental aspect of the present disclosure may be the voltage divider for sensing a voltage of at least 6 kV of an inner conductor of a power cable distributing electrical energy in a national grid. Alternatively, such a resistor assembly may be a component of such a voltage divider or comprise a component of such a voltage divider. In some embodiments, the resistor assembly comprises the high-voltage portion of a voltage divider for sensing a voltage of at least 6 kV vs. ground of an inner conductor of a power cable distributing electrical energy in a grid.

The substrate of a resistor assembly according to the present disclosure may be a mechanical support for other elements of the resistor assembly. The high-voltage contact may be supported by the substrate. The low-voltage contact may be supported by the substrate. The substrate may be, for example, a printed circuit board (“PCB”), such as a single layer PCB or a multilayer PCB, or comprise a PCB. A multilayer PCB may comprise one or more dielectric board layers. The substrate may comprise a fibre-reinforced polymeric material such as FR4. The substrate may be a single-layer or multilayer ceramic PCB or comprise a single-layer or multilayer ceramic PCB.

Alternatively, the substrate may be a ceramic body, e.g. a single-layer ceramic body or a multi-layer ceramic body.

The substrate of the resistor assembly is electrically non-conductive. The substrate may be, or comprise, a ceramic hydrocarbon material, such as the Rogers 4000 series PCB material. The substrate may alternatively be, or comprise, a PTFE (polytetrafluoroethylene) material or an epoxy material.

The resistor assembly may have an elongate shape, for example a flat rectangular shape. The rectangular shape defines a length and a width. The resistor assembly may have a rectangular shape having a length of between 10 cm and 50 cm, in particular a length of between 15 cm and 35 cm. It may have a rectangular shape having a width of between 1 cm and 5 cm, in particular a width of between 2 cm and 3 cm.

An elongate shape defines a first end portion and an opposed second end portion. The end portions may be spaced from each other in a length direction of the resistor assembly. The elongate shape of the resistor assembly may be defined by the shape of the substrate.

The resistor assembly comprises a high-voltage contact, arranged at the first end portion of the resistor assembly. The high-voltage contact is suitable for galvanic connection to the inner conductor. It may be adapted to be galvanically connected to the inner conductor, e.g. by being externally accessible on an outer surface of the resistor assembly. The high-voltage contact may comprise, for example, a soldering point to which a wire can be secured that is connected to the inner conductor. Alternatively, the high-voltage contact may be comprised, for example, in a connector, with which a matching connector can be mated to establish a galvanic connection with the inner conductor. In specific embodiments, the high-voltage contact is an exposed soldering point on an outer surface of a printed circuit board forming the substrate.

The resistor assembly also comprises a low-voltage contact, arranged at the second end portion of the resistor assembly. The low-voltage contact is suitable for connection to ground or to a low voltage of 10 V or less. It may be adapted to be electrically, e.g. galvanically, connected to electrical ground, e.g. by being externally accessible on an outer surface of the resistor assembly. The low-voltage contact may comprise, for example, a soldering point to which a wire can be secured for connection to a grounding element. Alternatively, the low-voltage contact may be comprised, for example, in a connector, with which a matching connector can be mated to establish an electrical connection to a grounding element. In specific embodiments, the low-voltage contact is an exposed soldering point on an outer surface of a printed circuit board forming the substrate.

In certain embodiments, the low-voltage contact may be the ground contact of the voltage divider for sensing the voltage of the inner conductor. In these embodiments, all electrical elements of the voltage divider, including its high-voltage side and its low-voltage side, may be accommodated on the substrate.

In other, alternative embodiments, the low-voltage contact may be the midpoint contact or pick-up contact of the voltage divider. In these embodiments, electrical elements (e.g. impedance elements or impedances) of the voltage divider forming its high-voltage side may be accommodated on the substrate. Electrical elements forming the low-voltage side of the voltage divider may be accommodated on the substrate or off, i.e. remote from, the substrate.

While the high-voltage contact is arranged at the first end portion of the resistor assembly, the low-voltage contact is arranged at the opposite, second end portion. It is arranged at a distance of at least 10 centimetres from the high-voltage contact. This distance helps reduce the risk of electrical discharge between the high-voltage contact and the low-voltage contact. In certain embodiments, however, the low-voltage contact is arranged at a distance of at least 15 centimetres, or of at least 20 centimetres, from the high-voltage contact. The distance is to be measured purely geometrically, as the length of a straight line between the closest portions of the high-voltage contact and the low-voltage contact. Conductive traces or exposed wire portions leading towards the high-voltage contact or towards the low-voltage contact are not supposed to be considered portions of the respective contact, as they are not adapted for connection, e.g. mechanical connection, to a wire or to a connector.

The distance between the high-voltage contact and the low-voltage contact of the impedance assembly according to the second fundamental aspect is at least 10 cm. The resistor layer extends between the first end portion and the second end portion of the resistor assembly. In order to facilitate a moderate voltage drop across the resistor layer and thus to reduce the risk of electrical discharges between an element on low voltage and an element on high voltage, the resistor layer should have an elongate shape. In other words, the resistor layer should extend lengthwise. Its length direction may be the direction between the first and the second end portion of the impedance assembly. The greater the length of the resistor layer, the smaller the risk of discharge between its ends. Therefore, in certain embodiments of the present disclosure, the resistor layer extends lengthwise for at least 100 mm. In certain of these embodiments, the resistor layer extends lengthwise for at least 120 mm. In certain embodiments, the resistor layer extends lengthwise for between 100 mm and 200 mm.

An impedance assembly according to the second fundamental aspect of the present disclosure may comprise both the high-voltage side and the low-voltage side of the voltage divider for sensing the voltage of the inner conductor. The low-voltage side of the voltage divider may also comprise a resistor layer. Hence, in certain embodiments, an impedance assembly comprising a (first) resistor layer as described herein further comprises a second resistor layer, electrically connected in series with the first resistor layer. The second resistor layer may be operable as a low-voltage side of the voltage divider for sensing a voltage of the inner conductor. A pickup point or midpoint may be provided electrically between the first and the second resistor layer on the substrate.

A sensored cable accessory as disclosed herein can form a portion of a voltage sensor for sensing a voltage of the inner conductor of a power-carrying conductor, such as a power cable, in a grid, such as a national grid. The sleeve with the impedance assembly, independent if according to the first or to second fundamental aspect of the present disclosure, may be ready to be applied around the power-carrying conductor.

In a further aspect, the present disclosure also provides a kit of parts for assembling a sensored cable accessory as described above, the kit comprising a) an elastic sleeve for electrically insulating a power-carrying conductor of a power cable, the sleeve having a longitudinal cavity for accommodating an impedance assembly as described herein, and b) an impedance assembly as described herein.

The impedance assembly in such a kit may, in particular, be embedded, entirely or partially, in an electrically non-conductive encapsulating material.

Such kits may be adapted to be assembled to form a portion of a voltage sensor for sensing the high voltage of the inner conductor of a MV/HV power cable. For assembly, the impedance assembly may be pushed into the cavity of the sleeve.

In a yet further aspect, the present disclosure provides a power network for distributing energy in a national grid, comprising a power-carrying conductor, and a voltage divider, electrically connected to the power-carrying conductor, for sensing an AC (i.e. alternating) high voltage of the power-carrying conductor, the voltage divider comprising an impedance assembly as described herein.

### BRIEF DESCRIPTION OF THE DRAWINGS

The invention will now be described in more detail with reference to the following Figures exemplifying particular embodiments of the invention. Some of the Figures may be not to scale, and certain dimensions, e.g. thicknesses, may be drawn exaggerated to enhance clarity.

FIG. 1 Circuit diagram of a voltage divider connected to a power cable;

FIG. 2 Longitudinal sectional view of a first impedance assembly according to the present disclosure;

FIG. 3 Longitudinal sectional view of a second impedance assembly according to the present disclosure, where the printed circuit board is a multilayer PCB;

FIG. 4 Longitudinal sectional view of a third impedance assembly, embedded in an encapsulating material;

FIG. 5 Perspective view of a fourth impedance assembly according to the present disclosure, accommodated in a cavity of an elastic sleeve;

FIG. 6 Longitudinal sectional view of a fifth impedance assembly according to the present disclosure, embedded in an encapsulating material provided with a split screen; and

FIG. 7 Top view of a sixth impedance assembly according to the present disclosure, comprising a resistor layer.

### DETAILED DESCRIPTION

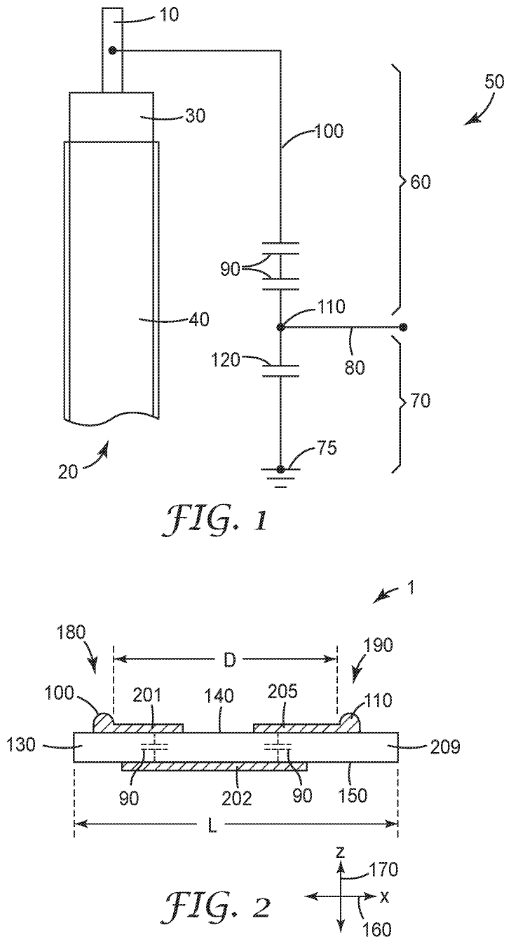

The circuit diagram of FIG. 1 illustrates a voltage divider for sensing a voltage of an inner conductor 10 of a power-carrying conductor, namely a high-voltage power cable 20. An end portion of the cable 20 is shown in plan view. It is stripped down, so that the main insulation layer 30 and a semiconductive layer 40 are visible, which surround the inner conductor 10. When the cable 20 is in use, the inner conductor 10 is typically at a voltage of between 1 kV and 175 kV vs. electrical ground and conducts alternating currents of tens of amperes up to hundreds of amperes.

For sensing the voltage of the inner conductor 10, a voltage divider 50 is electrically connected to the inner conductor 10 and to electrical ground 75. The voltage divider 50 comprises a high-voltage side 60 and a low-voltage side 70. A divided voltage can be picked up at an access point 80 of the voltage divider 50. The divided voltage is proportional to the voltage of the inner conductor 10, with the proportionality factor being the dividing ration of the voltage divider 50.

The high-voltage side 60 of the voltage divider 50 consists of two dividing capacitors 90, electrically connected in series between a high-voltage contact 100 and a low-voltage contact 110 of the voltage divider 50. The low-voltage contact 110 provides access to the divided voltage at the access point 80. In certain voltage dividers usable in the context of the present disclosure, each of the two dividing capacitors 90 has a capacitance of 40 pF, so that they provide a combined capacitance of 20 pF.

The low-voltage side 70 of the voltage divider 50 comprises a single capacitor, referred to as the low-voltage capacitor 120. It is connected between the midpoint 80 and electrical ground 75. In certain voltage dividers usable in the context of the present disclosure, the low-voltage capacitor 120 has a capacitance of 200 nF and an NP0 rating for temperature stability.

The dividing ratio of the voltage divider 50 is about 1:10 000. If the inner conductor 10 is at 50 kV, the output voltage of the voltage divider 50 at the low-voltage contact 110 is about 5 V. Voltages of that magnitude can be processed by standard electronic circuitry.

The large voltage drop across the two dividing capacitors 90 from 50 kV to 5 V on the high-voltage side 60 of the voltage divider 50 requires specific mechanical and electrical designs, as will be explained below.

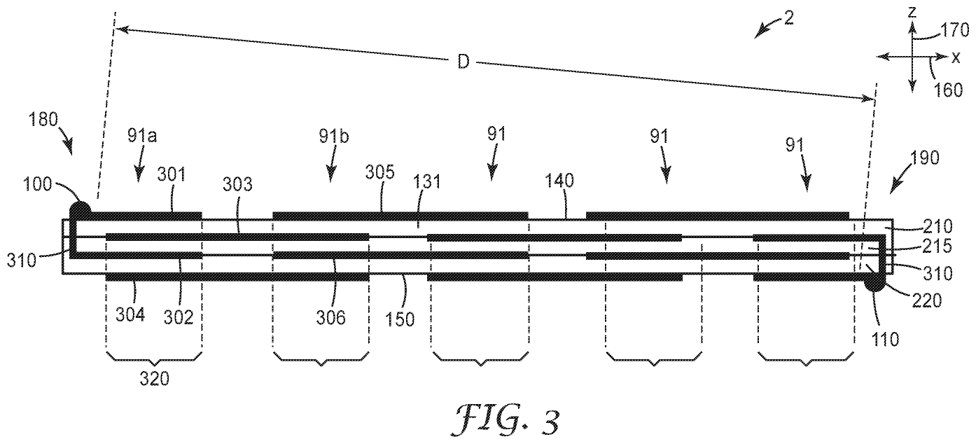

FIG. 2 is a longitudinal sectional view of a first impedance assembly 1 according to the present disclosure. The first impedance assembly 1 comprises a PCB 130 made of FR4 material. The PCB 130 has two major surfaces, an upper major surface 140 and an opposed lower major surface 150, in this example, and it is about 1 mm thick. The PCB 130 is a single-layer PCB 130, i.e. the substrate of the PCB 130 is formed by one single dielectric board layer 209.

The impedance assembly 1 has an elongate shape. It extends in length directions between a first end portion 180 and an opposed second end portion 190. Length (x−) directions of the impedance assembly 1 are indicated by arrow 160, and its thickness (z−) directions are indicated by arrow 170. Width directions are orthogonal to length directions 160 and thickness directions 170.

The impedance assembly 1 has a high-voltage contact 100 on its first end portion 180 for physical connection to an inner conductor 10 of a power cable 20, and a low-voltage contact 110 on its second end portion 190 for connection to a low voltage of 10 Volt or less. Both the high-voltage contact 100 and the low-voltage contact 110 comprise a respective soldering pad to facilitate connection of a wire. Two dividing capacitors 90 are electrically connected in series between the high-voltage contact 100 and the low-voltage contact 110. These dividing capacitors 90 are operable as a high-voltage side 60 of a voltage divider 50 for sensing the voltage of an inner conductor 10 of a power cable 20, as shown in FIG. 1.

Physically, the electrodes of each of the two dividing capacitors 90 are formed by opposed conductive areas, coated on the major surfaces 140, 150 of the PCB 130 as 12 μm thick copper layers. Thicker copper layers, such as 35 μm or 70 μm thick copper layers may be used alternatively. A first conductive area 201, arranged on the upper surface 140 of the PCB 130, and an opposed second conductive area 202, arranged on the lower surface 150, form the electrodes of the first (leftmost, in FIG. 2) dividing capacitor 90. The second conductive area 202 and a third conductive area 205 form the second dividing capacitor 90. Each of the two dividing capacitors 90 has a capacitance of about 24 pF, resulting in a combined capacitance of the two dividing capacitors 90 of about 12 pF.

The dielectric of each of the two dividing capacitors 90 is formed by respective portions of the substrate of the PCB 130, located between those portions of the opposed conductive areas 201, 202, 205 which are arranged directly opposite to each other.

The first conductive area 201 is connected to the high-voltage contact 100, and the third conductive area 205 is connected to the low-voltage contact 110.

The geometric distance D between the externally accessible portions of high-voltage contact 100 and of the low-voltage contact 110 is about 35 mm. This distance helps ensure that the risk of electrical discharges between any two electrodes 201, 202, 205 remains low, and that the risk of discharge between the high-voltage contact 100 and the low-voltage contact 110 is low.

The geometric length L of the impedance assembly 1 is about 50 mm, so that the impedance assembly 1 can be accommodated in a cavity of even a relatively short elastic sleeve for insulating a power cable 20.

FIG. 3 is a longitudinal sectional view of a second impedance assembly 2 according to the present disclosure. The second impedance assembly 2 comprises a multilayer ceramic PCB 131. The PCB 131 has two major surfaces: an upper major surface 140 and an opposed lower major surface 150, and it is about 2 mm thick.

The impedance assembly 2 has an elongate shape. It extends in length directions between a first end portion 180 and an opposed second end portion 190. Length (x) directions of the impedance assembly 1 are indicated by arrow 160, and its thickness (z) directions are indicated by arrow 170. Some dimensions in z direction are drawn exaggerated for greater clarity. Width directions are orthogonal to length directions 160 and thickness directions 170.

Like the first impedance assembly 1 of FIG. 2, the second impedance assembly 2 has a high-voltage contact 100 on its first end portion 180 for connection to an inner conductor 10 of a power cable 20, and a low-voltage contact 110 on the lower surface 150 of the second end portion 190 for connection to a low voltage of 10 Volt or less. Both the high-voltage contact 100 and the low-voltage contact 110 comprise a respective soldering pad to facilitate connection of a wire. Their geometric distance D between the high voltage contact and the low voltage contact is about 30 cm, with the length of the entire impedance assembly 2 being about 32 cm.

Different from the single-layer PCB 130 of the first impedance assembly 1, the PCB 131 of the second impedance assembly 2 is a multilayer PCB. It comprises three flat parallel dielectric board layers 210, 215, 220 in the PCB substrate, namely an upper dielectric board layer 210, a centre dielectric board layer 215 and a lower dielectric board layer 220. The dielectric board layers 210, 215, 220 consist of an electrically non-conductive ceramic material.

Five dividing capacitors 91 are electrically connected in series between the high-voltage contact 100 and the low-voltage contact 110. These dividing capacitors 91 are operable as a high-voltage side 60 of a voltage divider 50 for sensing the voltage of an inner conductor 10 of a power cable 20, as shown in FIG. 1.

Each of the dividing capacitors 91 is formed by four opposed conductive areas. This will be described for the leftmost dividing capacitor 91a. All other dividing capacitors 91 are formed in a comparable manner.

The leftmost dividing capacitor 91a (in FIG. 3) has two electrodes. The first electrode comprises a portion of a first conductive area 301 on the upper surface 140 of the upper dielectric board layer 210 of the PCB 131 and an opposed portion of a second conductive area 302 between the lower dielectric board layer 220 and the centre dielectric board layer 215. The first and the second conductive areas 301, 302 are electrically connected with each other by a via 310, which connects conductive areas in the thickness (z−) direction 170.

The second electrode of the dividing capacitor 91a comprises a portion of a third conductive area 303, arranged between the upper dielectric board layer 210 and the centre dielectric board layer 215, and a portion of a fourth conductive area 304 on the outer surface 150 of the lower dielectric board layer 220 of the PCB 131. The third and the fourth conductive areas 303, 304 are not conductively connected with each other or with another element, but are on floating potential. Only that portion of each respective conductive area 301, 302, 303, 304 forms the dividing capacitor 91a which overlaps with the other three conductive areas 301, 302, 303, 304. The size of the overlapping area of the four conductive areas 301, 302, 303, 304 forming the dividing capacitor 91a is about 30 mm in length direction 160 (indicated by bracket 320) and 20 mm in width direction. Each of the dividing capacitors 91 has a capacitance of about 100 pF, so that the combined capacitance of the five dividing capacitors 91, connected in series between the high-voltage contact 100 and the low-voltage contact 110, is about 20 pF.

The portions of the dielectric board layers 210, 215, 220 of the PCB 131 between the first and the third conductive areas 301, 303, between the third and the second conductive areas 303, 302, and between the second and the fourth conductive areas 302, 304 form the dielectric of the leftmost dividing capacitor 91a. The dielectric of the other dividing capacitors 91 is formed in the same manner by other portions of the respective dielectric board layer 210, 215, 220 on which the electrodes of the respective dividing capacitor 91 are arranged.

The ceramic material of the dielectric board layers 210, 215, 220 has a relative permittivity εᵣ of about 4.0. Due to the material being a ceramic material, its coefficient of thermal expansion is comparatively low, which keeps the distances between opposed conductive areas less variable with temperature variations, resulting in a less variable capacitance of the dividing capacitors 91. Also, electrical properties of a ceramic substrate generally vary less with ambient humidity than those of, for example, polymeric substrates, which reduces variations in the relative permittivity of the dielectric of the dividing capacitors 91, and thereby the corresponding variations of the capacitance of the dividing capacitors 91 with changes in humidity.

The adjacent dividing capacitor 91b (second from left in FIG. 3) is formed by a similar arrangement of conductive areas as the leftmost dividing capacitor 91a: a portion of a fifth conductive area 305 on the top surface 140 of the upper dielectric board layer 210 and a portion of a sixth conductive area 306 (arranged between the centre dielectric board layer 215 and the lower dielectric board layer 220) form the first electrode. A portion of the third conductive area 303 and an opposed portion of the fourth conductive area 304 form the second electrode of the adjacent dividing capacitor 91b.

The leftmost dividing capacitor 91a and the adjacent dividing capacitor 91b are electrically connected with each other in series by the third conductive area 303 and the fourth conductive area 304, which extend between the dividing capacitors and respective portions of which form an electrode of the leftmost dividing capacitor 91a and an electrode of the adjacent dividing capacitor 91b. The same applies to the other pairs of adjacent dividing capacitors 91. The resulting chain of dividing capacitors 91 (i.e. including the leftmost dividing capacitors 91a and 91b) of the second impedance assembly 2 is thus formed by the five dividing capacitors 91, electrically connected with each other in series.

Compared to the first impedance assembly 1, the additional conductive areas 302, 303, 306 in the interior of the PCB 131 of the second impedance assembly 2 help increase the capacitances of the respective dividing capacitors 91. However, the distance in z− (thickness−) direction between two opposed conductive areas in the second impedance assembly 2 is smaller than the corresponding distance between opposed conductive areas in the first impedance assembly 1. The smaller distance results in a higher risk of electrical discharge between opposed conductive areas, such as between the first conductive area 301 and the third conductive area 303. So in order to obtain a suitable dividing ratio of the voltage divider and at the same time limiting the risk of discharges, a suitable number of conductive areas in the interior of the PCB 131, such as conductive areas 302, 303, can be identified by calculation and standard experiments.

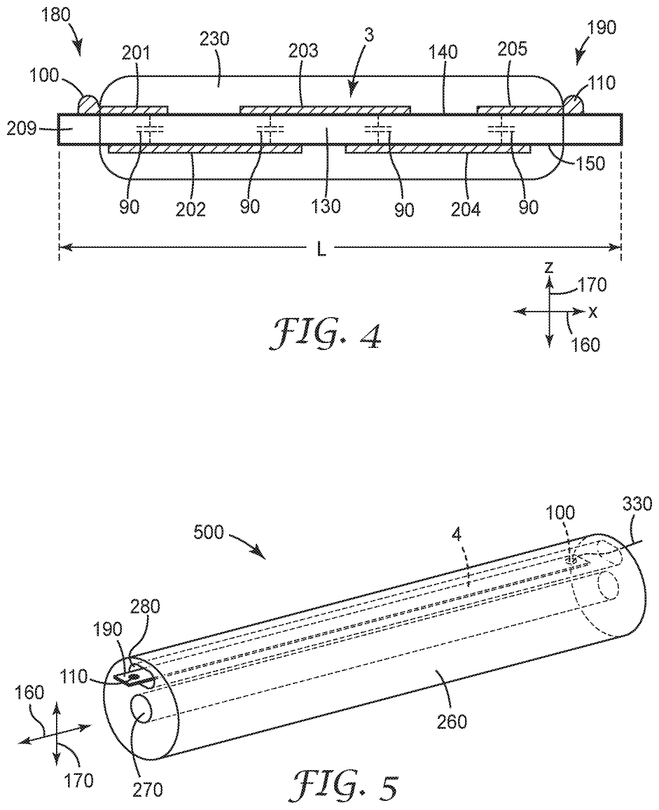

In order to further reduce the risk of electrical discharges between elements of an impedance assembly according to the present disclosure, the impedance assembly can be embedded in an electrically non-conductive encapsulating material. Such an embodiment is shown in FIG. 4 in a longitudinal sectional view. It illustrates a third impedance assembly 3, similar to the first impedance assembly 1 of FIG. 2, embedded in a body 230 of encapsulating material.

The third impedance assembly 3 differs from the first impedance assembly 1 in that it features four dividing capacitors 90, indicated by capacitor symbols in dotted lines, which are serially connected with each other to form the high-voltage side 60 of a voltage divider 50. The four dividing capacitors 90 are formed by opposed conductive areas 201, 202, 203, 204, 205 arranged on the outer surface of the single dielectric board layer 209 of the PCB 130. For example, the portion of the third conductive area 203 overlapping with the opposed portion of the fourth conductive area 204 forms one electrode of a dividing capacitor 90, with that overlapping portion of the fourth conductive area 204 forming the other electrode of that dividing capacitor 90. The portion of the (only) dielectric board layer 209 of the PCB 130 which lies between these two overlapping portions of the conductive areas 203, 204 forms the dielectric of that dividing capacitor 90.

The encapsulating material is an electrically insulating hardened casting resin. When the casting resin was still liquid, it was applied around the impedance assembly 3 in a suitably shaped mould and then let harden to become a solid body 230. The mould is shaped such that the body 230 leaves the first end portion 180 and the second end portion 190 free. Where the impedance assembly 3 is designed to be accommodated in a longitudinal cavity of an elastic sleeve, the body 230 is shaped such that its outer shape corresponds to the shape of the cavity of the elastic sleeve, in which the impedance assembly 3 with its encapsulating body 230 is to be accommodated.

The dielectric strength of the encapsulating body 230 is higher than that of air, so that the likelihood of electric discharges between elements, e.g. dividing capacitors 90, within the encapsulating body 230 is less than it would be in air.

In order to keep the high-voltage-contact 100 and the low-voltage contact 110 accessible, e.g. for connection of wires, only about 85% of the length L of the impedance assembly 3 are embedded in the encapsulating material. The end portions 180, 190 of the impedance assembly 3 remain free of encapsulating material.

FIG. 5 illustrates, in a perspective view, how an impedance assembly according to the present disclosure can be accommodated in a cavity of an elastic sleeve, thereby forming a sensored cable accessory 500. An elongate, tubular elastic sleeve 260 forms a longitudinal passageway 270, in which an inner conductor 10 of a cable 20 can be received. The sleeve 260 is made of EPDM and electrically insulates the inner conductor 10. The sleeve 260 also forms a longitudinal cavity 280, extending in the length direction 160 of the sleeve 260, parallel to the length direction 160 of the passageway 270. An impedance assembly 4, such as the impedance assemblies shown in FIGS. 2, 3, and 4, is accommodated in the cavity 280. A second end portion 190 of the impedance assembly 4, protrudes from the cavity 280, so that the low-voltage contact 110 is accessible from outside the sleeve 260 for connection to a low-voltage side 70 of a voltage divider 50. A wire 330 is connected to the high-voltage contact 100 of the impedance assembly 4. Its other end protrudes from the cavity 280 and can be connected to the inner conductor 10 of the power cable 20, or to a cable lug at an end of the power cable 20 to sense the AC high voltage of the inner conductor 10 of the power cable 20 versus ground.

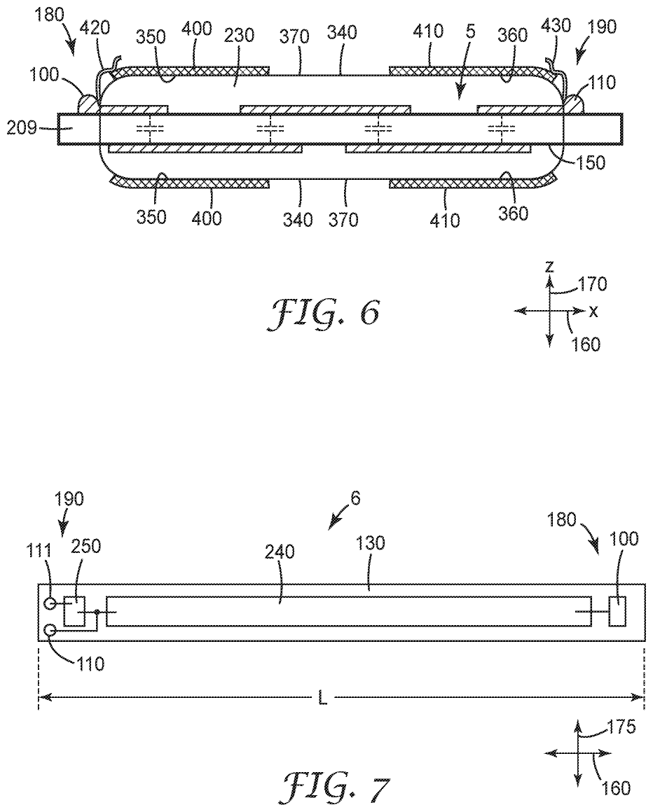

FIG. 6 is an illustration, in longitudinal sectional view, of a fifth impedance assembly 5, embedded in an encapsulating material 230 provided with a split screen. The fifth impedance assembly 5 is identical with the third impedance assembly 3 of FIG. 4. The encapsulation material 230 is identical with the encapsulation material 230 of FIG. 4, except that the outer surface 340 of the encapsulation material 230 is equipped with a split screen to reduce parasitic currents.

In length (x−) direction 160 of the elongate impedance assembly 5, the outer surface 340 of the encapsulation material 230 is subdivided into three regions: A first surface region 350, which is covered with a first electrically conductive layer 400, made of copper. The first conductive layer 400 extends circumferentially around, and thereby envelopes, the high-voltage portion, i.e. the left-hand side portion (in FIG. 6) of the impedance assembly 5.

The first conductive layer 400 can be connected to the high voltage of the power-carrying conductor via the high-voltage contact 100 and a first spring contact 420, which is attached to the high-voltage contact 100 and establishes a surface contact with the first conductive layer 400. In use, when the high-voltage contact 100 is electrically connected to the power-carrying conductor, the high voltage of the power-carrying conductor is present on the first conductive layer 400.

A second surface region 360 of the encapsulating material 230, spaced from the first surface region 350 in length direction 160, is covered with a second electrically conductive copper layer 410. The second conductive layer 410 extends circumferentially around, and thereby envelopes, the low-voltage portion, i.e. the right-hand side portion (in FIG. 6) of the impedance assembly 5.

The second conductive layer 410 can be connected to electrical ground via the low-voltage contact 110 and a second spring contact 430, which is attached to the low-voltage contact 110 and establishes a surface contact with the second conductive layer 410. In use, when the low-voltage contact 110 is electrically connected to ground, the ground potential is present on the second conductive layer 410.

A third surface region 370 is arranged lengthwise between the first surface region 350 and the second surface region 360 of the encapsulating material 230. There is no conductive layer in this third surface region 370, so that the third surface region 370 is electrically insulating. It forms a non-conductive gap between the first surface region 350 and the second surface region 360, and thereby electrically insulates the first surface region 350 and the second surface region 360 from each other. In FIG. 6, the third surface region 370 is shown as uncovered. Alternatively, it could be covered with an electrically insulating layer.

The extension of the third surface region 370 in length direction 160, i.e. the width of the insulating gap, can be chosen according to the actual circumstances and appropriately for avoiding electrical discharges between the first surface region 350 and the second surface region 360, across the insulating gap 370. Where the high-voltage contact 100 is on a high voltage of about 20 kV, and the impedance assembly 5 with its encapsulating material 230 is accommodated in a tight-fitting body of non-conductive silicone rubber, the width of the insulating gap 370 can be, for example, around 50 mm. For lower voltages, the insulating gap 370 can be narrower, for higher voltages it is preferably wider. Where there is no silicone rubber fitted tightly around the encapsulation material 230, the insulating gap 370 should normally be wider to reduce the risk of discharges.

The electrically conductive layers 400, 410 can, for example, be formed by thin layers of copper, vapor-deposited on the respective surface portions 350, 360 of the outer surface 340 of the encapsulating material 230.

A further embodiment of an impedance assembly according to the present disclosure is illustrated in top view in FIG. 7. This sixth impedance assembly 6 can be used as part of a resistive voltage divider for sensing the high voltage of an inner conductor of a power cable 20 such as the one shown in FIG. 1. The sixth impedance assembly 6 has an elongate shape and extends in length directions between a first end portion 180 and an opposed second end portion 190. Length (x) directions of the impedance assembly 3 are indicated by arrow 160, and its width (y) directions are indicated by arrow 175. Thickness directions are orthogonal to length directions 160 and width directions 175. The sixth impedance assembly 6 is a resistor assembly. It is designed for accommodation in a longitudinal cavity 280 of an elastic sleeve 260 for insulating a power cable.

The sixth impedance assembly 6 comprises a resistor layer 240, arranged on an outer surface of a substrate 130, namely a PCB 130, and extending between the first end portion 180 and the second end portion 190. A high-voltage contact 100, formed as s soldering point 100, is arranged on the first end portion 180, and it is designed to be galvanically connected to the inner conductor 10. The sixth impedance assembly 6 comprises two low-voltage contacts on the second end portion 190: a first low-voltage contact 110 and a second low-voltage contact 111. Both low-voltage contacts 110, 111 are soldering points, designed for connection to a low voltage of about 10 Volt or less. Both low-voltage contacts 110, 111 are arranged at a distance of about 12 cm from the high-voltage contact 100. The entire impedance assembly 6 has a length L of about 14 cm.

The resistor layer 240 provides a resistance, over its length, of about 200 MΩ. It is electrically connected in series between the high-voltage contact 100 and the first low-voltage contact 110. The resistor layer 240 is made of a high-resistance coating, such as a nickel-chromium-iron alloy for example, on the PCB 130. It is operable as a high-voltage side of a voltage divider, such as the voltage divider 50 shown in FIG. 1, between low voltage (or ground) and the high voltage of the inner conductor 10 of the cable 20. High voltage at the high-voltage contact 100 is divided down to about 10 Volt at the first low-voltage contact 110. The large surface of the resistor layer 240 dissipates heat effectively.

The sixth impedance assembly 6 comprises a further resistor, namely a low-voltage resistor 250, also formed as a surface resistor on the outer surface of the PCB 130. The low-voltage resistor 250 has a resistance of about 20 kΩ. It is connected in series between the high-voltage contact 100 and the second low-voltage contact 111. It is operable as the low-voltage side of a voltage divider between the high voltage and ground. The second low-voltage contact 111 is a soldering pad, adapted to be connected to electrical ground. The sixth impedance assembly 6 thus comprises an entire resistive voltage divider, namely the high-voltage side 60 and the low-voltage side 70. The first low-voltage contact 110 can be the access point of this resistive voltage divider, and the output voltage, picked up from the first low-voltage contact 110, measured against electrical ground, is proportional to the high voltage of the inner conductor 10, the proportionality factor being the dividing ratio between the resistance of the low-voltage resistor 250 and the resistance of the resistor layer 240, hence 20 kΩ/200 MΩ=1:10000.

1. Impedance assembly for use in a voltage divider for sensing an AC voltage of at least 1 kV versus ground of a power-carrying conductor distributing electrical energy in a national grid,
wherein the impedance assembly comprises
a) a printed circuit board comprising one or more dielectric board layers,
b) an externally accessible high-voltage contact,
c) an externally accessible low-voltage contact, wherein any externally accessible portion of the low-voltage contact is spaced from any externally accessible portion of the high-voltage contact by a geometrical distance (D) of at least 30 mm, and
d) at least two dividing capacitors, electrically connected in series between the high-voltage contact and the low-voltage contact and operable as a high-voltage side of the voltage divider,
wherein each dividing capacitor has
two electrodes formed by opposed conductive areas, arranged on opposed surface portions of a specific dielectric board layer of the one or more dielectric board layers,
a dielectric arranged between the electrodes and comprising a portion of the specific dielectric board layer on which the electrodes are arranged.

2. Impedance assembly according to claim 1, wherein the at least two dividing capacitors are electrically connected in series between the high-voltage contact and the low-voltage contact such as to provide a combined capacitance of at least 10 picofarad.

3. Impedance assembly according to claim 1, comprising a total of six dividing capacitors, electrically connected in series between the high-voltage contact and the low-voltage contact such as to provide a combined capacitance of at least 10 picofarad, and operable as a high-voltage side of the voltage divider between the low voltage and the high voltage of the power-carrying conductor,
wherein each dividing capacitor has two electrodes formed by opposed conductive areas arranged on opposed surface portions of a specific dielectric board layer of the one or more dielectric board layers, and a dielectric arranged between the electrodes and comprising a portion of the specific dielectric board layer on which the electrodes are arranged.

4. Impedance assembly according to claim 1, wherein the at least two dividing capacitors are electrically connected in series between the high-voltage-contact and the low-voltage contact such as to provide a combined capacitance of at least 50 picofarad.

5. Impedance assembly according to claim 1, wherein the printed circuit board is a multilayer printed circuit board, and wherein at least two of the conductive areas are arranged in the interior of the printed circuit board.

6. Impedance assembly according to claim 1, wherein the printed circuit board is a ceramic PCB.

7. Impedance assembly according to claim 1, wherein at least one of the dielectric board layers comprises a ceramic material.

8. Impedance assembly according to claim 1, wherein each dielectric board layer comprises a ceramic material.

9. Impedance assembly according to claim 1, wherein the impedance assembly has an elongate shape and a length of 30 centimetres or less.

10. Impedance assembly according to claim 1, wherein at least a portion of the impedance assembly is embedded in an electrically non-conductive encapsulating material.

11. Impedance assembly according to claim 10, wherein the outer surface of the encapsulation material comprises
a first surface region covered with an electrically conductive layer for being connected to high voltage;
a second surface region covered with an electrically conductive layer for being connected to electrical ground; and
a third surface region, electrically insulating and free of an electrically conductive layer, arranged between the first surface region and the second surface region, for insulating the first surface region from the second surface region.

12. Impedance assembly for use in a voltage divider for sensing an AC voltage of between 6 kV and 175 kV of an inner conductor of a power cable distributing electrical energy in a grid,
wherein the impedance assembly has an elongate shape defining a first end portion and an opposed second end portion, for accommodation in a longitudinal cavity of an elastic sleeve for insulating the power cable, and wherein the impedance assembly comprises
a) a substrate,
b) a high-voltage contact, arranged at the first end portion, for galvanic connection to the inner conductor,
c) a low-voltage contact, arranged at the second end portion at a distance of at least 12 centimetres from the high-voltage contact, for electrical connection to a low voltage of 10 volt or lower, and
d) a resistor layer, arranged on an inner or an outer surface of the substrate and extending between the first end portion and the second end portion, electrically connected in series between the high-voltage contact and the low-voltage contact such as to provide a resistance of at least 50 MΩ,
wherein the resistor layer is operable as a high-voltage side of the voltage divider between the low voltage and the high voltage of the inner conductor.

13. Impedance assembly according to claim 12, wherein the resistor layer extends lengthwise for at least 100 mm.

14. Impedance assembly according to claim 12, further comprising a second resistor layer, electrically connected in series with the first resistor layer, operable as a low-voltage side of the voltage divider for sensing a voltage of the inner conductor.

15. Impedance assembly for use in a voltage divider for sensing an AC voltage of between 6 kV and 175 kV of an inner conductor of a power cable distributing electrical energy in a grid,
wherein the impedance assembly has an elongate shape defining a first end portion and an opposed second end portion, for accommodation in a longitudinal cavity of an elastic sleeve for insulating the power cable, and wherein the impedance assembly comprises
a) a substrate,
b) a high-voltage contact, arranged at the first end portion, for galvanic connection to the inner conductor,
c) a low-voltage contact, arranged at the second end portion at a distance of at least 12 centimetres from the high-voltage contact, for electrical connection to a low voltage of 10 volt or lower, and
d) a plurality of impedance elements, arranged on an inner or an outer surface of the substrate and extending between the first end portion and the second end portion, electrically connected in series between the high-voltage contact and the low-voltage contact such as to provide a resistance of at least 50 MΩ, wherein the voltage divider is mixed, such that one dividing impedance element is of one type and the other dividing impedance element is of a different type,
wherein one dividing impedance is operable as a high-voltage side of the voltage divider between the low voltage and the high voltage of the inner conductor.

16. Sensored cable accessory, comprising
a) a cable termination, comprising an elastic sleeve for electrically insulating a power-carrying conductor of a power cable, the sleeve having a longitudinal cavity for accommodating an impedance assembly according to claim 1, and
b) an impedance assembly according to claim 1, arranged in the cavity of the sleeve.

17. Sensored cable accessory, comprising
a) a cable plug, comprising an elastic sleeve for electrically insulating a power-carrying conductor of a power cable, the sleeve having a longitudinal cavity for accommodating an impedance assembly according to claim 1, and
b) an impedance assembly according to claim 1, arranged in the cavity of the sleeve.

18. Kit of parts for assembling a sensored cable accessory, the kit comprising
a) an elastic sleeve for electrically insulating a power-carrying conductor of a power cable, the sleeve having a longitudinal cavity for accommodating an impedance assembly according to claim 1, and
b) an impedance assembly according to claim 1.

19. Power network for distributing energy in a grid, comprising a power-carrying conductor, and a voltage divider, connected to the power-carrying conductor, for sensing an AC high voltage of the power-carrying conductor, the voltage divider comprising an impedance assembly according to claim 1.
